(19) United States
(12) Patent Application Publication
(10) Pub. No.: US 2005/0076579 A1
(43) Pub. Date: Apr. 14, 2005

(54) Bicine/tricine containing composition and method for chemical-mechanical planarization

(76) Inventors: Junaid Ahmed Siddiqui, Richmond, VA (US); Timothy Frederick Compton, Casa Grande, AZ (US); Bin Hu, Chandler, AZ (US); Robin Edward Richards, Phoenix, AZ (US); Saifi Usmani, Chandler, AZ (US)

Correspondence Address: AIR PRODUCTS AND CHEMICALS, INC.;PATENT DEPARTMENT, 7201 HAMILTON BOULEVARD, ALLENTOWN, PA, 181951501, US

(21) Appl. No.: 10/683,233

(22) Filed: Oct. 10, 2003

(51) Int. Cl. B24D 3/02; H01L 21/302; H01L 21/461

(52) U.S. Cl. 51/307; 451/28; 438/692; 438/693; 51/308; 51/309

(57) ABSTRACT

A composition and associated method for chemical mechanical planarization (or other polishing) are described. The composition comprises an abrasive and a tricine-type or bicine-type compound. The composition possesses high selectivities for removal of copper in relation to tantalum and dielectric materials whilst minimizing local dishing and erosion effects in CMP. The composition may further comprise an oxidizing agent in which case the composition is particularly useful in conjunction with the associated method for metal CMP applications (e.g., copper CMP).

### BACKGROUND OF THE INVENTION

This invention relates generally to the chemical-mechanical polishing (CMP) of metal substrates on semiconductor wafers and slurry compositions therefor. In particular, the present invention relates to a CMP slurry composition which is characterized to possess high selectivities for removal of copper in relation to tantalum and dielectric materials whilst minimizing local dishing and erosion effects during CMP processing of substrates comprised of metal, barrier material, and dielectric material. This invention is especially useful for copper CMP and most especially for copper CMP step 1.

Chemical mechanical planarization (chemical mechanical polishing, CMP) for planarization of semiconductor substrates is now widely known to those skilled in the art and has been described in numerous patents and open literature publications. Some introductory references on CMP are as follows: “Polishing Surfaces for Integrated Circuits”, by B. L. Mueller and J. S. Steckenrider, Chemtech, February, 1998, pages 38-46; and H. Landis et al., Thin Solids Films, 220 (1992), page 1.

In a typical CMP process, a substrate (e.g., a wafer) is placed in contact with a rotating polishing pad attached to a platen. A CMP slurry, typically an abrasive and chemically reactive mixture, is supplied to the pad during CMP processing of the substrate. During the CMP process, the pad (fixed to the platen) and substrate are rotated while a wafer carrier system or polishing head applies pressure (downward force) against the substrate. The slurry accomplishes the planarization (polishing) process by chemically and mechanically interacting with the substrate film being planarized due to the effect of the rotational movement of the pad relative to the substrate. Polishing is continued in this manner until the desired film on the substrate is removed with the usual objective being to effectively planarize the substrate. Typically metal CMP slurries contain an abrasive material, such as silica or alumina, suspended in an oxidizing, aqueous medium.

Silicon based semiconductor devices, such as integrated circuits (ICs), typically include a silicon dioxide dielectric layer. Multilevel circuit traces, typically formed from aluminum or an aluminum alloy or copper, are patterned onto the silicon dioxide substrate.

CMP processing is often employed to remove and planarize excess metal at different stages of semiconductor manufacturing. For example, one way to fabricate a multilevel copper interconnect or planar copper circuit traces on a silicon dioxide substrate is referred to as the damascene process. In a semiconductor manufacturing process typically used to form a multilevel copper interconnect, metallized copper lines or copper vias are formed by electrochemical metal deposition followed by copper CMP processing. In a typical process, the interlevel dielectric (ILD) surface is patterned by a conventional dry etch process to form vias and trenches for vertical and horizontal interconnects and make connection to the sublayer interconnect structures. The patterned ILD surface is coated with an adhesion-promoting layer such as titanium or tantalum and/or a diffusion barrier layer such as titanium nitride or tantalum nitride over the ILD surface and into the etched trenches and vias. The adhesion-promoting layer and/or the diffusion barrier layer is then overcoated with copper, for example, by a seed copper layer and followed by an electrochemically deposited copper layer. Electro-deposition is continued until the structures are filled with the deposited metal. Finally, CMP processing is used to remove the copper overlayer, adhesion-promoting layer, and/or diffusion barrier layer, until a planarized surface with exposed elevated portions of the dielectric (silicon dioxide and/or low-k) surface is obtained. The vias and trenches remain filled with electrically conductive copper forming the circuit interconnects.

When one-step copper CMP processing is desired, it is usually important that the removal rate of the metal and barrier layer material be significantly higher than the removal rate for dielectric material in order to avoid or minimize dishing of metal features or erosion of the dielectric. Alternatively, a multi-step copper CMP process may be employed involving the initial removal and planarization of the copper overburden, referred to as a step 1 copper CMP process, followed by a barrier layer CMP process. The barrier layer CMP process is frequently referred to as a barrier or step 2 copper CMP process. Previously, it was believed that the removal rate of the copper and the adhesion-promoting layer and/or the diffusion barrier layer must both greatly exceed the removal rate of dielectric so that polishing effectively stops when elevated portions of the dielectric are exposed. The ratio of the removal rate of copper to the removal rate of dielectric base is called the “selectivity” for removal of copper in relation to dielectric during CMP processing of substrates comprised of copper, tantalum and dielectric material. The ratio of the removal rate of copper to the removal rate of tantalum is called the “selectivity” for removal of copper in relation to tantalum during CMP processing. When CMP slurries with high selectivity for removal of copper and tantalum in relation to dielectric are used, the copper layers are easily over-polished creating a depression or “dishing” effect in the copper vias and trenches. This feature distortion is unacceptable due to lithographic and other constraints in semiconductor manufacturing.

Another feature distortion that is unsuitable for semiconductor manufacturing is called “erosion.” Erosion is the topography difference between a field of dielectric and a dense array of copper vias or trenches. In CMP, the materials in the dense array maybe removed or eroded at a faster rate than the surrounding field of dielectric. This causes a topography difference between the field of dielectric and the dense copper array.

A typically used CMP slurry has two actions, a chemical component and a mechanical component. An important consideration in slurry selection is “passive etch rate.” The passive etch rate is the rate at which copper is dissolved by the chemical component alone and should be significantly lower than the removal rate when both the chemical component and the mechanical component are involved. A large passive etch rate leads to dishing of the copper trenches and copper vias, and thus, preferably, the passive etch rate is less than 10 nanometers per minute.

A number of systems for CMP of copper have been disclosed. A few illustrative examples are listed next. Kumar et al. in an article entitled “Chemical-Mechanical Polishing of Copper in Glycerol Based Slurries” (Materials Research Society Symposium Proceedings, 1996) disclose a slurry that contains glycerol and abrasive alumina particles. An article by Gutmann et al. entitled “Chemical-Mechanical Polishing of Copper with Oxide and Polymer Interlevel Dielectrics” (Thin Solid Films, 1995) discloses slurries based on either ammonium hydroxide or nitric acid that may contain benzotriazole (BTA) as an inhibitor of copper dissolution. Luo et al. in an article entitled “Stabilization of Alumina Slurry for Chemical-Mechanical Polishing of Copper” (Langmuir, 1996) discloses alumina-ferric nitrate slurries that contain polymeric surfactants and BTA. Carpio et al. in an article entitled “Initial Study on Copper CMP Slurry Chemistries” (Thin Solid Films, 1995) disclose slurries that contain either alumina or silicon particles, nitric acid or ammonium hydroxide, with hydrogen peroxide or potassium permanganate as an oxidizer.

In relation to copper CMP, the current state of this technology involves use of a two-step process to achieve local and global planarization in the production of IC chips. During step 1 of a copper CMP process, the overburden copper is removed. Then step 2 of the copper CMP process follows to remove the barrier layer and achieve both local and global planarization. Generally, after removal of overburden copper in step 1, polished wafer surfaces have non-uniform local and global planarity due to differences in the step heights at various locations of the wafer surfaces. Low density features tend to have higher copper step heights whereas high density features tend to have low step heights. Due to differences in the step heights after step 1, step 2 copper CMP selective slurries with respect to tantalum to copper removal rates and copper to oxide removal rates are highly desirable. The ratio of the removal rate of tantalum to the removal rate of copper is called the “selectivity” for removal of tantalum in relation to copper during CMP processing of substrates comprised of copper, tantalum and dielectric material.

There are a number of theories as to the mechanism for chemical-mechanical polishing of copper. An article by Zeidler et al. (Microelectronic Engineering, 1997) proposes that the chemical component forms a passivation layer on the copper changing the copper to a copper oxide. The copper oxide has different mechanical properties, such as density and hardness, than metallic copper and passivation changes the polishing rate of the abrasive portion. The above article by Gutmann et al. discloses that the mechanical component abrades elevated portions of copper and the chemical component then dissolves the abraded material. The chemical component also passivates recessed copper areas minimizing dissolution of those portions.

These are two general types of layers that can be polished. The first layer is interlayer dielectrics (ILD), such as silicon oxide and silicon nitride. The second layer is metal layers such as tungsten, copper, aluminum, etc., which are used to connect the active devices.

In the case of CMP of metals, the chemical action is generally considered to take one of two forms. In the first mechanism, the chemicals in the solution react with the metal layer to continuously form an oxide layer on the surface of the metal. This generally requires the addition of an oxidizer to the solution such as hydrogen peroxide, ferric nitrate, etc. Then the mechanical abrasive action of the particles continuously and simultaneously removes this oxide layer. A judicious balance of these two processes obtains optimum results in terms of removal rate and polished surface quality.

In the second mechanism, no protective oxide layer is formed. Instead, the constituents in the solution chemically attack and dissolve the metal, while the mechanical action is largely one of mechanically enhancing the dissolution rate by such processes as continuously exposing more surface area to chemical attack, raising the local temperature (which increases the dissolution rate) by the friction between the particles and the metal and enhancing the diffusion of reactants and products to and away from the surface by mixing and by reducing the thickness of the boundary layer.

While prior art CMP systems are capable of removing a copper overlayer from a silicon dioxide substrate, the systems do not satisfy the rigorous demands of the semiconductor industry. These requirements can be summarized as follows. First, there is a need for high removal rates of copper to satisfy throughput demands. Secondly, there must be excellent topography uniformity across the substrate. Finally, the CMP method must minimize local dishing and erosion effects to satisfy ever increasing lithographic demands.

### BRIEF SUMMARY OF THE INVENTION

In one embodiment, the invention is a polishing composition comprising:
a) an abrasive; and
b) a tricine-type or bicine-type compound having the structure:
   C(((CH₂)ₙ-A)(CH₂)ₘ—B)(CH₂)ₚ-D))—N(R₁)—(CH₂)_{q}—COOH
   or
   (((CH₂)ₙ-A)(CH₂)ₘ—B))—N(R₁)—(CH₂)_{q}—COOH
   where n, m, p, and q are independently 1-3; A, B, and D are independently selected from the group consisting of hydrido, hydroxyl, chloro, fluoro, bromo, and alkoxy; and R₁ is selected from the group consisting of hydrogen and C₁-C₃ alkyl.

The polishing composition is useful in chemical-mechanical polishing (CMP), especially in metal CMP.

In another embodiment, the invention is a method of polishing comprising the steps of:
A) placing a substrate in contact with a polishing pad;
B) delivering a polishing composition comprising a) an abrasive; and b); a tricine-type or bicine-type compound having the structure:
   C(((CH₂)ₙ-A)(CH₂)ₘ—B)(CH₂)ₚ-D))—N(R₁)—(CH₂)_{q}—COOH
   or
   (((CH₂)ₙ-A)(CH₂)ₘ—B))—N(R₁)—(CH₂)_{q}—COOH
   where n, m, p, and q are independently 1-3; A, B, and D are independently selected from the group consisting of hydrido, hydroxyl, chloro, fluoro, bromo, and alkoxy; and R₁ is selected from the group consisting of hydrogen and C₁-C₃ alkyl; and
C) polishing the substrate with the polishing composition.

### DETAILED DESCRIPTION OF THE INVENTION

It has been found that CMP polishing compositions comprising a) an abrasive and b) a tricine-type or bicine-type compound possess high selectivities for removal of copper in relation to tantalum and dielectric materials whilst minimizing local dishing and erosion effects during CMP processing, and are consequently particularly useful in step 1 copper CMP processing. Furthermore, selectivities for these CMP polishing compositions are tunable depending upon the level of the tricine-type or bicine-type compound in a given composition.

In one embodiment, the CMP slurry of this invention comprises a) an abrasive and b) a tricine-type compound. In another embodiment, the CMP slurry of this invention comprises a) an abrasive and b) a bicine-type compound. For metal CMP applications, the stable CMP slurry in these embodiments further comprises c) an oxidizing agent. Optionally, other additives may be included.

Suitable tricine-type or bicine-type compounds include, but are not limited to, compounds having the structure:
C(((CH₂)ₙ-A)(CH₂)ₘ—B)(CH₂)ₚ-D))—N(R₁)—(CH₂)_{q}—COOH
or
(((CH₂)ₙ-A)(CH₂)ₘ—B))—N(R₁)—(CH₂)_{q}—COOH
where n, m, p, and q are independently 1-3; A, B, and D are independently selected from the group consisting of hydrido, hydroxyl, chloro, fluoro, bromo, and alkoxy; and R₁ is selected from the group consisting of hydrogen and C₁-C₃ alkyl.

Preferably, A, B, and D in the tricine-type or bicine-type compound are other than hydrido, more preferably they are hydroxyl, and most preferably the tricine-type compound is tricine itself and the bicine-type compound is bicine itself.

Tricine and other tricine-type compounds as well as bicine and other bicine-type compounds serve a dual function in CMP compositions. Firstly, they act as chelating agents and secondly, they serve as pH-adjusting agents to lower pH (due to the carboxylic acid functionality).

Both standard (unmodified) abrasives and organometallic-modified abrasives can be employed in this invention. Suitable unmodified abrasives include, but are not limited to, silica, alumina, titania, zirconia, germania, ceria, and co-formed products thereof, and mixtures thereof. An organometallic-modified abrasive obtained by treatment of an unmodified abrasive (e.g., silica) with an organometallic compound can also be employed in this invention. Suitable organometallic compounds for modification include aluminum acetate, aluminum formate, and aluminum propionate. Suitable abrasives include, but are not limited to, colloidal products, fumed products, and mixtures thereof.

Silica or organometallic-modified silica is a preferred abrasive material used in the present invention. The silica may be, for example, colloidal silica, fumed silica and other silica dispersions; however, the preferred silica is colloidal silica.

The abrasive is present in the slurry in a concentration of about 0.1 weight % to about 20 weight % of the total weight of the slurry. More preferably, the abrasive is present in a concentration of about 0.5 weight % to about 17 weight % of the total weight of the slurry. Most preferably, the abrasive is present in a concentration of about 1 weight % to about 15 weight % of the total weight of the slurry.

In embodiments of this invention having an oxidizing agent, the oxidizing agent can be any suitable oxidizing agent. Suitable oxidizing agents include, for example, one or more per-compounds, which comprise at least one peroxy group (—O—O—). Suitable per-compounds include, for example, peroxides, persulfates (e.g., monopersulfates and dipersulfates), percarbonates, and acids thereof, and salts thereof, and mixtures thereof. Other suitable oxidizing agents include, for example, oxidized halides (e.g., chlorates, bromates, iodates, perchlorates, perbromates, periodates, and acids thereof, and mixtures thereof, and the like), perboric acid, perborates, percarbonates, peroxyacids (e.g., peracetic acid, perbenzoic acid, m-chloroperbenzoic acid, salts thereof, mixtures thereof, and the like), permanganates, chromates, cerium compounds, ferricyanides (e.g., potassium ferricyanide), mixtures thereof, and the like. Preferred oxidizing agents include, for example, hydrogen peroxide, urea-hydrogen peroxide, sodium peroxide, benzyl peroxide, di-t-butyl peroxide, peracetic acid, monopersulfuric acid, dipersulfuric acid, iodic acid, and salts thereof, and mixtures thereof.

In compositions of this invention directed to metal CMP, (hydrogen peroxide) H₂O₂ is used as a preferred oxidizing agent. Preferably the concentration of the H₂O₂ is from about 0.2 weight % to about 6 weight % of the total weight of the slurry.

Other chemicals that may be added to the CMP slurry composition include, for example, pH adjusting agents, surfactants, acids, corrosion inhibitors, fluorine-containing compounds, chelating agents, non-polymeric nitrogen-containing compounds, and salts.

Suitable surfactant compounds that may be added to the slurry composition include, for example, any of the numerous nonionic, anionic, cationic or amphoteric surfactants known to those skilled in the art. The surfactant compounds may be present in the slurry composition in a concentration of about 0 weight % to about 1 weight %, preferably about 0.0005 weight % to about 1 weight % and, more preferably in a concentration of about 0.001 weight % to about 0.5 weight % of the total weight of the slurry. The preferred types of surfactants are nonionic, anionic, or mixtures thereof and are most preferably present in a concentration of about 10 ppm to about 1000 ppm of the total weight of the slurry. Nonionic surfactants are most preferred. A preferred nonionic surfactant is Surfynol® 104E, which is a 50:50 weight percent mixture of 2,4,7,9-tetramethyl-5-decyn-4,7-diol and ethylene glycol, (Air Products and Chemicals, Allentown, Pa.).

The pH-adjusting agent is used to improve the stability of the polishing composition, to improve the safety in use or to meet the requirements of various 06473 USA regulations. As a pH-adjusting agent to be used to lower the pH of the polishing composition of the present invention, hydrochloric acid, nitric acid, sulfuric acid, chloroacetic acid, tartaric acid, succinic acid, citric acid, malic acid, malonic acid, various fatty acids, various polycarboxylic acids may be employed. On the other hand, as a pH-adjusting agent to be used for the purpose of raising the pH, potassium hydroxide, sodium hydroxide, ammonia, tetramethylammonium hydroxide, ethylenediamine, piperazine, polyethyleneimine, etc., may be employed. The polishing composition of the present invention is not particularly limited with respect to the pH, but it is usually adjusted to pH 3 to 10.

In metal CMP applications, compositions having acidic or neutral pH values are generally preferred according to this invention. In this case, a suitable slurry pH is from about 3 to about 9, preferably from about 6.5 to about 8.5, and more preferably, from about 7 to about 8.

Other suitable acid compounds that may be added (in place of or in addition to the pH-adjusting acids mentioned supra) to the slurry composition include, but are not limited to, formic acid, acetic acid, propanoic acid, butanoic acid, pentanoic acid, hexanoic acid, heptanoic acid, octanoic acid, nonanoic acid, lactic acid, hydrochloric acid, nitric acid, phosphoric acid, sulfuric acid, hydrofluoric acid, malic acid, tartaric acid, gluconic acid, citric acid, phthalic acid, pyrocatechoic acid, pyrogallol carboxylic acid, gallic acid, tannic acid, and mixtures thereof. These acid compounds may be present in the slurry composition in a concentration of about 0 weight % to about 5 weight % of the total weight of the slurry.

Suitable corrosion inhibitors that may be added to the slurry composition include, for example, benzotriazole, 6-tolylytriazole, tolyltriazole derivatives, 1-(2,3-dicarboxypropyl)benzotriazole, N-acyl-N-hydrocarbonoxyalkyl aspartic acid compounds, and mixtures thereof. The corrosion inhibitor may be present in the slurry in a concentration of about 0 ppm to about 4000 ppm, preferably from about 10 ppm to about 4000 ppm, and more preferably from about 50 ppm to about 200 ppm of the total weight of the slurry. Two preferred corrosion inhibitors are CDX2128 and CDX2165, both supplied by King Industries, which are preferably present in a concentration of about 50 ppm to about 1000 ppm of the total weight of the slurry.

Carboxylic acids, if added, may also impart corrosion inhibition properties to the slurry composition.

To increase the selectivity of tantalum and tantalum compounds relative to silicon dioxide, fluorine-containing compounds may be added to the slurry composition. Suitable fluorine-containing compounds include, for example, hydrogen fluoride, perfluoric acid, alkali metal fluoride salt, alkaline earth metal fluoride salt, ammonium fluoride, tetramethylammonium fluoride, ammonium bifluoride, ethylenediammonium difluoride, diethylenetriammonium trifluoride, and mixtures thereof. The fluorine-containing compounds may be present in the slurry composition in a concentration of about 0 weight % to about 5 weight %, preferably from about 0.65 weight % to about 5 weight %, and more from about 0.50 weight % to about 2.0 weight % of the total weight of the slurry. A preferred fluorine-containing compound is ammonium fluoride, which is preferably present in a concentration from about 0.45 weight % to about 1.0 weight % of the total weight of the slurry.

Suitable non-polymeric nitrogen-containing compounds (amines, hydroxides, etc.) that may be added to the slurry composition include, for example, ammonium hydroxide, hydroxylamine, monoethanolamine, diethanolamine, triethanolamine, diethyleneglycolamine, N-hydroxylethylpiperazine, and mixtures thereof. These non-polymeric nitrogen-containing compounds may be present in the slurry composition in a concentration of about 0 weight % to about 1 weight %, and, if present, are normally present at a level of about 0.01 weight % to about 0.20 weight % of the total weight of the slurry. A preferred non-polymeric nitrogen-containing compound is ammonium hydroxide and is most preferably present in a concentration of about 0.01 weight % to about 0.1 weight % of the total weight of the slurry.

Suitable salts that optionally may be added to the slurry composition include, for example, ammonium persulfate, potassium persulfate, potassium sulfite, potassium carbonate, ammonium nitrate, potassium hydrogen phthalate, hydroxylamine sulfate, and mixtures thereof. The salts may be present in the slurry composition in a concentration of about 0 weight % to about 10 weight %, and, if present, are normally present at a level of about 0.02 weight % to about 5 weight % of the total weight of the slurry.

Still other chemicals that can be added to the slurry compositions are biological agents such as bactericides, biocides and fungicides especially if the pH is around about 6 to 9. Suitable biocides, include, but are not limited to, 1,2-benzisothiazolin-3-one; 2(hydroxymethyl)amino ethanol; 1,3-dihydroxymethyl-5,5-dimethylhydantoin; 1-hydroxymethyl-5,5-dimethylhydantion; 3-iodo-2-propynyl-butylcarbamate; glutaraldehyde; 1,2-dibromo-2,4-dicyanobutane; 5-chloro-2-methyl-4-isothiazoline-3-one; 2-methyl-4-isothiazolin-3-one; and mixtures thereof.

Associated Methods

The associated methods of this invention entail use of the aforementioned composition (as disclosed supra) for chemical mechanical planarization of substrates comprised of metals and dielectric materials. In the methods, a substrate (e.g., a wafer) is placed face-down on a polishing pad which is fixedly attached to a rotatable platen of a CMP polisher. In this manner, the substrate to be polished and planarized is placed in direct contact with the polishing pad. A wafer carrier system or polishing head is used to hold the substrate in place and to apply a downward pressure against the backside of the substrate during CMP processing while the platen and the substrate are rotated. The polishing composition (slurry) is applied (usually continuously) on the pad during CMP processing to effect the removal of material to planarize the substrate.

The composition and associated methods of this invention are effective for CMP of a wide variety of substrates, including substrates having dielectric portions that comprise materials having dielectric constants less than 3.3 (low-k materials). Suitable low-k films in substrates include, but are not limited to, organic polymers, carbon-doped oxides, fluorinated silicon glass (FSG), inorganic porous oxide-like materials, and hybrid organic-inorganic materials. Representative low-k materials and deposition methods for these materials are summarized below.

| | | Deposition | |
|---|---|---|---|
| Vendor | Trade Name | Method | Material |
| Air Products and | MesoElk ® | Spin-on | Hybrid organic- |
| Chemicals | | | inorganic |
| Applied Materials | Black Diamond | CVD | Carbon-doped oxide |
| Dow Chemical | SiLK ™, | Spin-on | Organic polymer |
| | Porous SiLK ™ | | |
| Honeywell | NANOGLASS ® E | Spin-on | Inorganic oxide-like |
| Electronic | | | |
| Materials | | | |
| Novellus Systems | CORAL ® | PECVD | Carbon-doped oxide |

PECVD = Plasma enhanced chemical vapor deposition
CVD = chemical vapor deposition

Similarly, the composition and associated methods of this invention are effective for CMP of substrates comprised of various metals, including, but not limited to, tantalum, titanium, tungsten and copper.

While not being bound by any particular theory, the inventors believe that the considerations presented in the next paragraph may explain why a polishing composition comprising a) an abrasive and b) a tricine-type or bicine-type compound exhibits high selectivities for removal of copper in relation to tantalum and dielectric materials whilst minimizing local dishing and erosion effects during CMP processing, and are consequently particularly useful in step 1 copper CMP processing.

The main purpose of adding a chelating agent to a copper CMP formulation is to increase the copper removal rate by increasing the solubility of copper ions in solution via a copper complexation/dissolution reaction. This complexation/dissolution reaction also promotes the removal rate of tantalum, which is a barrier layer between the metal copper layer and the dielectric layer. Thus, use of a strong chelating agent, e.g. citric acid, in a CMP formulation results in low copper to tantalum selectivity and hence a high level of copper dishing. In the present invention, a novel chelating agent, e.g. tricine or bicine, is included in the slurry formulation to dramatically increase copper to tantalum selectivity while simultaneously affording a low level of dishing. Compared to citric acid and other multiligand chelating agents, tricine or bicine has only one carboxylic acid together with a sterically crowded amino group. Under basic conditions (pH greater than 7), the carboxylic group exists as a carboxylate anion, which can effectively complex copper ions. Both copper and tantalum are metals. Copper has an atomic number of 23 whereas tantalum has an atomic number of 73. Due to the small radius of a copper ion, a carboxylate anion readily forms a tight “ion pair” with a copper ion. This tight ion pair formation is believed to be one factor that results in high copper removal rates for 06473 USA the inventive compositions in copper CMP. In addition, it is well known that copper ions forms complexes readily with acetic acid under low acidic as well as basic conditions with no need for a second chelating group. Unlike copper, tanalum has a large atomic radius, which fact has consequences from the standpoint of tantalum removal rates in CMP. As the atomic radius of a metal ion increases, a carboxylate anion tends to make a loose “ion pair” with this metal ion, which fact is believed to correspond to low tantalum removal rates. Furthermore, compared to copper, tantalum forms highly basic oxides, forms weak complexes with carboxylate conjugate base anions, and has large ionic radius. All these factors discourage tantalum complex formation further. Consequently, in the tricine or bicine molecule, a combination of high steric crowding of the amino group and poor complexing ability of carboxylate anion with tantalum leads to relatively low tantalum removal rates in relation to copper removal rates and thus results in high copper to tantalum selectivities.

Furthermore, selectivities for these CMP polishing compositions are tunable depending upon the level of the tricine-type or bicine-type compound in a given composition.

The present invention is further demonstrated by the examples below.

GLOSSARY

| | |
|---|---|
| COMPONENTS | |
| Blanket Wafers: | Blanket wafers are those that have typically one type of surface |
| | prepared for polishing experiments. These are either |
| | electrochemically deposited copper, PVD tantalum or PETEOS. |
| | The blanket wafers used in this work were purchased from Silicon |
| | Valley Microelectronics, 1150 Campbell Aye, CA, 95126. |
| | The film thickness specifications are summarized below: |
| IC1000 ™ Pad | Rodel ® IC1000 ™ pads were used for step I copper CMP. The |
| | pads had K-groove and Suba IV sub-pad. Rodel ® is based in |
| | Newark, DE. |
| Politex ™ Pad | Polishing pad used during step II copper CMP, supplied by |
| | Rodel ®, Newark, DE. |
| S104E | Surfynol ® 104E - a 50:50 mixture by weight of |
| | 2,4,7,9-tetramethyl-5-decyn-4,7-diol and |
| | ethylene glycol (solvent), Air Products and |
| | Chemicals, Allentown, PA. |
| TEOS | Tetraethyl orthosilicate |
| Triazole | 1,2,4-Triazole (Aldrich Chemical Co., Milwaukee, Wisconsin) |
| Tricine | N-[tris(hydroxymethyl)methyl]glycine, CAS # 5704-04-1 |
| | The structure of tricine is as follows: |
| | 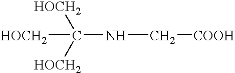 |
| General | |
| Å: | angstrom(s) - a unit of length |
| BP: | back pressure, in psi units |
| CMP: | chemical mechanical planarization = chemical |
| | mechanical polishing |
| CS: | carrier speed |
| DF: | Down force: pressure applied during chemical mechanical |
| | planarization, units psi |
| min: | minute(s) |
| ml: | milliliter(s) |
| mV: | millivolt(s) |
| psi: | pounds per square inch |
| PS: | platen rotational speed of polishing tool, in rpm |
| | (revolution(s) per minute) |
| SF: | slurry flow, ml/min |
| Removal Rates | |
| Cu RR 4.5 psi | Measured copper removal rate at 4.5 psi down pressure of the |
| | CMP tool |
| Cu RR 2 psi | Measured copper removal rate at 2 psi down pressure of the CMP |
| | tool |
| PETEOS RR 2 psi | Measured PETEOS removal rate at 2 psi down pressure of the |
| | CMP tool |
| Ta RR 2 psi | Measured tantalum removal rate at 2 psi down pressure of the |
| | CMP tool |
| TEOS RR 2 psi | Measured TEOS removal rate at 2 psi down pressure of the CMP |
| | tool |
| Selectivities | |
| Cu: Ta Sel | Copper: Tantalum Selectivity - the ratio of the amount of copper |
| | removed to the amount of tantalum removed during CMP |
| | experiments under identical conditions. |
| Cu: TEOS | Copper TEOS (or PETEOS) Selectivity - The ratio of the amount |
| (or PETEOS) Sel | of copper removed to the amount of TEOS (or PETEOS) (dielectric |
| | material) removed during CMP experiments under identical |
| | conditions. |
| Dishing Parameters | |
| 100 μm dishing | The dishing delta was calculated by the difference in dishing |
| delta (center) | values measured before and after processing with a slurry |
| | formulation. The measurements were conducted on a P-15 |
| | Surface Profiler at approximately the same specific location at the |
| | center of a copper pattern wafer. |
| 100 μm dishing | The dishing delta was calculated by the difference in dishing |
| delta (edge) | values measured before and after processing with a slurry |
| | formulation. The measurements were conducted on a P-15 |
| | Surface Profiler at approximately the same specific location at the |
| | edge of a copper pattern wafer. |
| Ave. dishing delta | Average dishing delta refers to the average value calculated from |
| | the 100 μm dishing delta calculated at the “center” and “edge” |
| | locations on the copper pattern wafers. |
| Dishing Values | (See discussion infra on dishing measurements/values) |

### EXAMPLES

General

All percentages are weight percentages and all temperatures are degrees Centigrade unless otherwise indicated.

Chemical Mechanical Planarization (CMP) Methodology

In the examples presented below, chemical mechanical planarization (CMP) experiments were run using the procedures and experimental conditions given below.

Metrology

PETEOS thickness was measured with a Nanometrics, model, # 9200, manufactured by Nanometrics Inc, 1550 Buckeye, Milpitas, Calif. 95035-7418. The metal films were measured with a ResiMap CDE, model 168, manufactured by Creative Design Engineering, Inc, 20565 Alves Dr, Cupertino, Calif., 95014. This tool is a four-point probe sheet resistance tool. Twenty-five and forty nine-point polar scans were taken with the respective tools at 3-mm edge exclusion. Planarity measurements were conducted on a P-15 Surface Profiler manufactured by KLA® Tencore, 160 Rio Robles, San Jose, Calif. 95161-9055.

CMP Tool

The CMP tool that was used is a Mirra®, manufactured by Applied Materials, 3050 Boweres Avenue, Santa Clara, Calif., 95054. A Rodel Politex® embossed pad, supplied by Rodel, Inc, 3804 East Watkins Street, Phoenix, Ariz., 85034, was used on the platen for the blanket wafer studies. Pads were broken-in by polishing twenty-five dummy oxide (deposited by plasma enhanced CVD from a TEOS precursor, PETEOS) wafers. In order to qualify the tool settings and the pad break-in, two PETEOS monitors were polished with Syton OX-K® colloidal silica, supplied by DuPont Air Products NanoMaterials L.L.C., at baseline conditions.

In blanket wafers studies, groupings were made to simulate successive film removal: first copper, next tantalum, and finally the PETEOS. The tool mid-point conditions were: table speed; 123 rpm, head speed; 112 rpm, membrane pressure, 2.0 psi; inter-tube pressure, 0.0 psi; slurry flow, 200 ml/min.

Dishing Measurements Using Patterned Copper Wafers

Dishing is defined as the difference between the final oxide level of a wafer and the lowest point within the copper line of the wafer after executing a CMP process on the wafer. In pattern wafer studies described in the examples below, wafers which had been previously used for other experiments were re-used to examine the impact of the slurry formulations on incremental dishing as a function of slurry composition. As a consequence of being used, the used patterned wafers typically had copper overburden removed with most of the remaining copper inside the patterned lines. The rest of the wafer surface was either remaining TEOS or Ta barrier. The influence of the slurry formulations on these used patterned wafers was determined by subjecting these used pattern wafers to CMP processing under comparable polishing conditions for a duration of 30 seconds with these formulations. The level of dishing was determined in the following manner. Dishing for 100 μm Cu lines was measured before processing with the slurry formulations. These values were typically between 600 Å to 1200 Å. The wafers were processed on the Mirra® tool. After processing with the slurry formulations described in this invention, the dishing values on the same features at the same locations on the wafer were measured again. The difference between the values measured before and after processing the wafers with slurry formulations was then calculated as the 100 μm dishing delta for the slurry. These 100 μm dishing delta values are listed in Tables 2 and 3.

Blanket Wafers

Polishing experiments were conducted using electrochemically deposited copper, tantalum, and PETEOS wafers. These blanket wafers were purchased from Silicon Valley Microelectronics, 1150 Campbell Ave, Calif., 95126. The film thickness specifications are summarized below:
PETEOS: 15,000 Å on silicon
Copper: 10,000 Å electroplated copper/1,000 Å copper seed/250 Å Ta on silicon
Tantalum: 2000 Å/5,000 Å thermal oxide on silicon.
   Zeta Potential Measurements

Zeta potential measurements were made using a Colloidal Dynamics instrument, manufactured by Colloidal Dynamics Corporation, 11-Knight Street, Building E8, Warwick, R.I. 02886. This instrument measures the zeta potential (surface charge) of colloidal particles, such as surface-modified colloidal silica particles.

Polishing of Copper Pattern Wafers

The used copper pattern wafers 854CMP025 were processed on the Mirra® tool configured with a IC1000™ pad described earlier. The process conditions were the following: membrane pressure 2.0 psi, retaining ring pressure 3.0 psi, inner tube pressure 2.2 psi. The platen speed was 119 rpm; the carrier speed was 113 rpm. The slurry flow was 150 ml/min. The wafers were processed for 30 seconds.

### Examples 1 and 3 in Table 1

In Table 1, Example 1 and Example 3 are inventive examples using bicine and tricine, respectively, whereas Example 2 is a comparative example using citric acid. In Example 1, in addition to bicine, the formulation also contains DP106 as an abrasive, H₂O₂, triazole, H₂O, polyamidopolyethyleneimine, and CDX2165 as shown in Table 1. In Example 3, in addition to tricine, the formulation also contains DP106 as an abrasive, H₂O₂, triazole, H₂O, polyamidopolyethyleneimine (BASF Corporation, 36 Riverside Ave., Rensselaer, N.Y., 12144), and CDX2165 as shown in Table 1.

The polishing formulations were used to polish copper, tantalum, and TEOS blanket wafers at 4.5 psi and 2 psi. The removal rate and selectivity data are tabulated in Table 1 under Example 1 and Example 3. The tricine-containing formulation gave copper to tantalum selectivity of 65 and copper to TEOS selectivity of 36 whereas the bicine-containing formulation gave copper to tantalum selectivity of 32 and copper to TEOS selectivity of 20.

### Example 2

### Comparative Example

In Table 1, Example 2 is a comparative example showing the use of citric acid as a chelating agent instead of tricine or bicine. The polishing formulation containing citric acid, DP106, H₂O, triazole, H₂O₂, polyamidopolyethyleneimine, and CDX2165 (with component amounts as shown in Table 1) was used to polish copper, tantalum, and TEOS blanket wafers under identical polishing conditions as were used in Examples 1 and 3. The removal rate and selectivity data that were obtained are tabulated in Table 1. Compared to control experiment in Example 2, both Examples 1 and 3 gave high copper to tantalum and copper to TEOS selectivities. More specifically, the (inventive) tricine-based formulation, tested in Example 3, gave copper to tantalum selectivity of 65 at 2 psi whereas in the control citric acid-based formulation, tested in Example 2, copper to tantalum selectivity of 10.6 was obtained. Similarly, compared to the control experiment, the (inventive) bicine-based formulation gave high copper to tantalum, and copper to oxide selectivities.

### Examples 4, 5, and 6 in Table 2

These examples demonstrate the comparison between a tricine-based composition and a bicine-based composition versus a citric acid-based polishing composition in the presence of triazole on the level of dishing measured on patterned wafers. The compositions used are shown in Table 2. As shown in Table 2, the average dishing level of the tricine-based composition (Example 5) was 386 μm versus an average dishing level of 625 μm for the citric acid-based composition (Comparative Example 4). Interestingly, the bicine and tricine based formulations were essentially equivalent in dishing performance. More specifically, dishing at 100 micron line for the tricine-based formulation (Example 5) was 386 μm versus 345 um for the bicine-based formulation (Example 6).

### Example 7, 8, and 9 in Table 3

The Examples 7-9 further demonstrate comparisons between a tricine-based composition and a bicine-based composition versus a citric acid-based polishing composition. As shown in Table 3, the average dishing level of the tricine-based composition (Example 9) was 113 μm on 100 micron metal line versus an average dishing level of 705 μm on 100 micron line for the citric acid-base composition (Comparative Example 7). Interestingly, the bicine-based and tricine based formulations were essentially comparable in dishing performance. More specifically, dishing for the tricine-based formulation in Example 9 was 113 μm versus 100 μm for the bicine-based formulation in Example 8.

TABLE 1
Comparison of Bicine- Tricine- and Citric Acid-Based
CMP Slurries with Respect to Selectivities

| | | Example 2 | |
|---|---|---|---|
| | Example 1 | (Comparative) | Example 3 |
| Formulation | 0.5% Bicine | 0.5% Citric acid | 0.5% Tricine |
| | 2.5% DP106 | 2.5% DP106 | 2.5% DP106 |
| | 0.2% Triazole | 0.2% Triazole | 0.2% Triazole |
| | 0.05% | 0.05% | 0.05% |
| | polyamidopoly- | polyamidopoly- | polyamidopoly- |
| | ethyleneimine | ethyleneimine | ethyleneimine |
| | 0.1% CDX2165 | 0.1% CDX2165 | 0.1% CDX2165 |
| | 95.35% H₂O | 95.35% H₂O | 95.35% H₂O |
| | 1.3% H₂O₂ | 1.3% H₂O₂ | 1.3% H2O2 |
| | pH 7.5 | pH 7.5 | pH 7.5 |
| Cu RR 4.5 psi | 3740 Å/min | 3733 Å/min | 3950 A/min |
| Cu RR 2 psi | 730 Å/min | 870 Å/min | 1120 A/min |
| TEOS RR | 36 Å/min | 51 Å/min | 31 A/min |
| 2 psi | | | |
| Ta RR 2 psi | 23 Å/min | 82 Å/min | 17 A/min |
| Cu: TEOS Sel | 20 | 17 | 36 |
| at 2 psi | | | |
| Cu: Ta Sel at | 32 | 10.6 | 65 |
| 2 psi | | | |

TABLE 2
Comparison of Bicine-, Tricine- and Citric acid-Based
CMP Slurries with Respect to Dishing

| | Example 4 | | |
|---|---|---|---|
| | (Comparative) | Example 5 | Example 6 |
| Formulation | 0.8% Citric acid | 0.8% Tricine | 0.8% Bicine |
| | 2.5% DP106 | 2.5% DP106 | 2.5% DP106 |
| | 94.725% H₂O | 94.725% H₂O | 94.725% H₂O |
| | 0.675% Triazole | 0.675% Triazole | 0.675% Triazole |
| | 1.3% H₂O₂ | 1.3% H₂O₂ | 1.3% H₂O₂ |
| | pH 7.5 | pH 7.5 | pH 7.5 |
| Cu RR 2 psi | 2365 Å/min | 2732 Å/min | 1664 Å/min |
| Cu RR 0.1 psi | 171 Å/min | 205 Å/min | 78 Å/min |
| 100 μm dishing | 650 μm | 370 μm | 320 μm |
| center (delta) | | | |
| 100 μm dishing | 600 μm | 400 μm | 370 μm |
| edge (delta) | | | |
| Ave. Dishing | 625 μm | 386 μm | 345 μm |

TABLE 3
Additional Comparison of Bicine-, Tricine- and Citric acid-Based
CMP Slurries with Respect to Dishing

| | Example 7 | | |
|---|---|---|---|
| | (Comparative) | Example 8 | Example 9 |
| Formulation | 0.5% Citric acid | 0.5% Bicine | 0.5% Tricine |
| | 2.5% Dp 106 | 2.5% DP106 | 2.5% DP106* |
| | 0.1% CDX2165 | 0.1% CDX2165 | 0.1% CDX2165 |
| | 0.05% | 0.05% | 0.05% |
| | polyamidopoly- | polyamidopoly- | polyamidopoly- |
| | ethyleneimine | ethyleneimine | ethyleneimine |
| | 95.35% H2O | 95.35% H2O | 93.45% H2O |
| | 0.2% Triazole | 0.20% Triazole | 0.20% Triazole |
| | 1.3% H₂O₂ | 1.3% H₂O₂ | 1.3% H₂O₂ |
| | pH 7.5 | pH 7.5 | pH 7.5 |
| Cu RR 2 psi | 870 Å/min | 730 Å/min | 1120 Å/min |
| Cu RR 0.1 psi | 45 Å/min | 25 Å/min | 62 Å/min |
| 100 μm dishing | 680 μm | 100 μm | 125 μm |
| center (delta) | | | |
| 100 μm dishing | 730 μm | 100 μm | 100 μm |
| edge (delta) | | | |
| Ave. Dishing | 705 μm | 100 μm | 113 μm |

1. A polishing composition comprising:
a) an abrasive; and
b) a tricine-type or bicine-type compound having the structure:
C(((CH₂)ₙ-A)(CH₂)ₘ—B) (CH₂)ₚ-D))—N(R₁)—(CH₂)_{q}—COOH
or
(((CH₂)ₙ-A)(CH₂)ₘ—B))—N(R₁)—(CH₂)_{q}—COOH
where n, m, p, and q are independently 1-3; A, B, and D are independently selected from the group consisting of hydrido, hydroxyl, chloro, fluoro, bromo, and alkoxy; and R₁ is selected from the group consisting of hydrogen and C₁-C₃ alkyl.

2. The polishing composition of claim 1 wherein the abrasive is a colloidal abrasive.

3. The polishing composition of claim 1 further comprising c) an oxidizing agent.

4. The polishing composition of claim 1 wherein the abrasive is silica.

5. A method of polishing comprising the steps of:
A) placing a substrate in contact with a polishing pad;
B) delivering a polishing composition comprising a) an abrasive; and b); a tricine-type or bicine-type compound having the structure:
C(((CH₂)ₙ-A)(CH₂)ₘ—B)(CH₂)ₚ-D))—N(R₁)—(CH₂)_{q}—COOH
or
(((CH₂)ₙ-A)(CH₂)ₘ—B))—N(R₁)—(CH₂)_{q}—COOH
where n, m, p, and q are independently 1-3; A, B, and D are independently selected from the group consisting of hydrido, hydroxyl, chloro, fluoro, bromo, and alkoxy; and R₁ is selected from the group consisting of hydrogen and C₁-C₃ alkyl; and
C) polishing the substrate with the polishing composition.

6. The method of claim 5 wherein the abrasive is a colloidal abrasive.

7. The method of claim 5 wherein the composition further comprises c) an oxidizing agent.

8. The method of claim 5 wherein the abrasive is silica.

9. The method of claim 5 wherein the polishing composition has a pH in the range of 6.5-8.5.
